(19) United States
(12) Patent Application Publication
(10) Pub. No.: US 2006/0264021 A1
(43) Pub. Date: Nov. 23, 2006

(54) Offset solder bump method and apparatus

(75) Inventors: Mohammad M. Farahani, Austin, TX (US); Priyavadan R. Patel, Chandler, AZ (US); Sriram Muthukumar, Chandler, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/131,828

(22) Filed: May 17, 2005

(51) Int. Cl. H01L 21/44; H01L 29/40; H01L 23/52; H01L 23/48

(52) U.S. Cl. 438/612; 257/779

(57) ABSTRACT

An apparatus, method, and system for integrated circuit packaging having an offset solder bump are disclosed herein. A semiconductor substrate has a bond pad and a passivation layer located on an active surface thereof. A solder terminal contacts both the bond pad and passivation layer. A solder bump contacts the solder terminal and is positioned laterally offset from the bond pad.

### FIELD OF THE INVENTION

Disclosed embodiments of the present invention relate to the field of integrated circuits, and more particularly to integrated circuit packaging.

### BACKGROUND OF THE INVENTION

With the advancement of integrated circuit technology, the need to miniaturize integrated circuit packaging to meet the needs of this integrated circuit technology has increased exponentially. This requirement has resulted in chip-scale packaging, wherein the ultimate goal is to have both the integrated circuit and the integrated circuit package be virtually the same size.

An integrated circuit package usually includes a mounting substrate and an integrated circuit, such as a semiconductor chip or die. The integrated circuit is located on or in the mounting substrate. One class of chip packaging includes integrated circuits that having metallization, on an active surface thereof. Contacts such as solder bumps are typically associated with the metallization, for purposes of electrically connecting the integrated circuit metallization to solder deposits on the mounting substrate.

As miniaturization of the integrated circuit progresses, the structure and arrangement of the junction between the metallization of the integrated circuit and the solder bump may result in physical strains on the integrated circuit and/or unexpected migration of materials within the integrated circuit environment.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 is a cross sectional view illustrating an electronic assembly, in accordance with some embodiments of the present invention;

FIG. 2 is a cross sectional view illustrating an example electronic assembly after patterning of a passivation layer above a metallization layer, in accordance with an embodiment of the present invention;

FIG. 3 is a cross sectional view illustrating an example electronic assembly depicted in FIG. 2 after further processing, in accordance with an embodiment of the present invention;

FIG. 4 is a cross sectional view illustrating an example electronic assembly depicted in FIG. 3 after further processing, in accordance with an embodiment of the present invention;

FIG. 5 is a cross sectional view illustrating an example electronic assembly depicted in FIG. 4 after further processing, in accordance with an embodiment of the present invention;

FIG. 6 is a cross sectional view illustrating an example electronic assembly depicted in FIG. 5 after further processing, in accordance with an embodiment of the present invention;

FIG. 7 is a cross sectional view illustrating an example electronic assembly depicted in FIG. 6 after further processing, in accordance with an embodiment of the present invention;

FIG. 8 is a cross sectional view illustrating an example electronic assembly depicted in FIG. 7 after further processing, in accordance with an embodiment of the present invention;

FIG. 9 is a cross sectional view illustrating an example electronic assembly depicted in FIG. 8 after further processing, in accordance with an embodiment of the present invention; and

FIG. 10 is a system including an electronic assembly in accordance with an embodiment of the present invention.

### DETAILED DESCRIPTION OF EMBODIMENTS OF THE INVENTION

An apparatus, method, and system for providing an offset solder bump adapted to limit physical strain on an integrated circuit in an electronic assembly is disclosed herein. In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the embodiments of the present invention. It should also be noted that directions and references (e.g., up, down, top, bottom, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

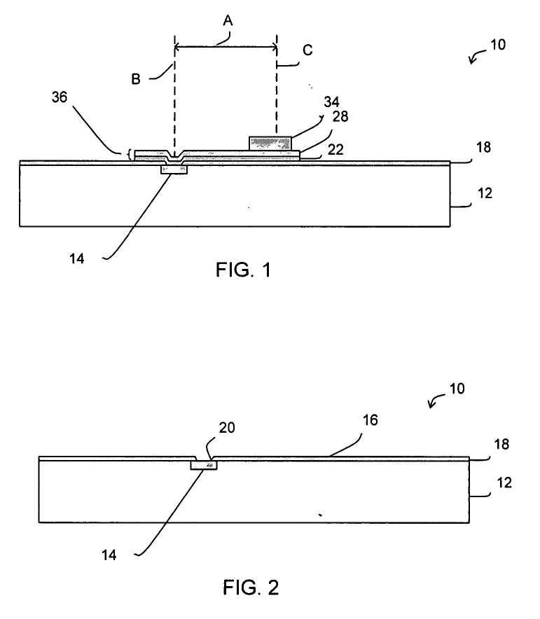

FIG. 1 illustrates a portion of an electronic assembly 10, in accordance with one embodiment. The electronic assembly 10 may include an integrated circuit formed in a rectangular piece of semiconductor substrate 12 called a chip or a die. Examples of the material suitable for a semiconductor substrate 12 include, but are not limited to silicon, silicon on sapphire, and gallium arsenide. In some embodiments of the present invention, the integrated circuit of electronic assembly 10 may be a processor. For example the integrated circuit of electronic assembly 10 may be a microprocessor.

FIG. 2 illustrates an example electronic assembly 10 at a given stage of processing, in accordance with an embodiment of the present invention. Electronic assembly 10 may include a metallization 14 located on an active surface 16 of the semiconductor substrate 12. The metallization 14 may be a bond pad. The bond pad 14 may be positioned to be co-planar with the active surface 16 of the semiconductor substrate 12.

A passivation layer 18 may be formed over the active surface 16 of the semiconductor substrate 12. The passivation layer 18 may be adapted to protect the semiconductor substrate 12. The passivation layer 18 may be formed of a single layer of material, or may alternatively be formed of multiple layers of material. The passivation layer 18 may be formed of any suitable material, according to the requirements of the particular application. Examples of materials suitable for forming the passivation layer 18 include, but are not limited to inorganic material (such as silicon nitride, silicon oxide, and silicon oxynitride), polyimide material (such as polyimide/silicon nitride, polyimide/silicon oxide, and polyimide/silicon oxynitride), combinations thereof, and the like.

The passivation layer 18 may include a pad opening 20 positioned over bond pad 14. The pad opening 20 exposes at least a portion of the bond pad 14. Pad opening 20 may be formed in the passivation layer 18 with a mask and etch process (not shown).

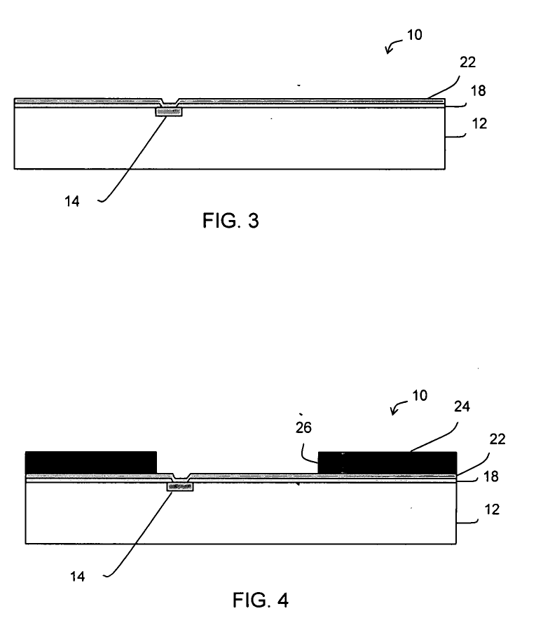

FIG. 3 illustrates an example electronic assembly 10 at a given stage of processing, in accordance with an embodiment of the present invention. A layer of BLM 22 may be deposited on top of the passivation layer 18. In embodiments where the solder bumps are non-lead based, the BLM 22 may typically be a is barrier layer metallurgy; whereas in embodiments where the solder bumps are lead based, the BLM 22 may typically be a ball limiting metallurgy. The BLM 22 may contact both the bond pad 14 and the passivation layer 18. The BLM 22 may be deposited by any suitable method, according to the requirements of the particular application. Examples of methods suitable for depositing the BLM 22 include, but are not limited to sputtering, physical vapor deposition (PVD), and the like. The BLM 22 may be formed of any suitable material, according to the requirements of the particular application. Examples of materials suitable for forming BLM 22 include, but are not limited to titanium, nickel, chromium, copper, tantalum, nickel, vanadium, aluminum, and the like.

FIG. 4 illustrates an example electronic assembly 10 at a given stage of processing, in accordance with an embodiment of the present invention. Once the layer of BLM 22 is deposited, a mask 24 may be applied over the BLM 22. The mask 24 may be patterned to expose at least a portion of the BLM 22 through an exposure 26. The mask 24 may be applied by any suitable method, according to the requirements of the particular application. For example, the mask 24 may be spun on, cured, exposed, and patterned to form exposure 26 over BLM 22.

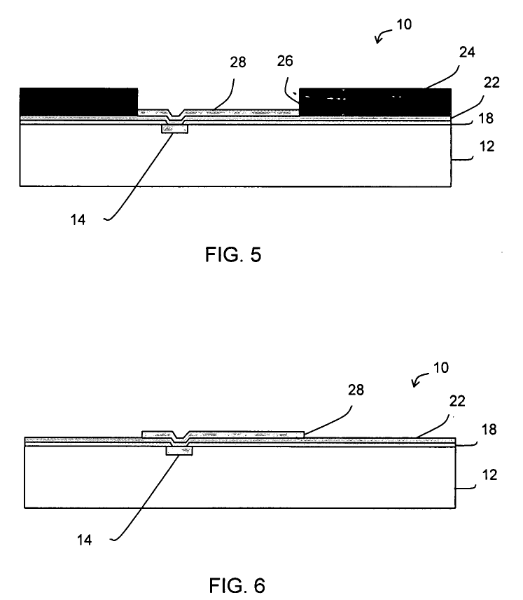

FIG. 5 illustrates an example electronic assembly 10 at a given stage of processing, in accordance with an embodiment of the present invention. Once the mask 24 is patterned to form exposure 26, a metallization layer 28 may be deposited on top of the layer of BLM 22. The metallization layer 28 may be deposited by any suitable method, according to the requirements of the particular application. Examples of methods suitable for depositing the metallization layer 28 include, but are not limited to electroplating, electroless plating, physical vapor deposition (PVD), and the like. The metallization layer 28 may be formed of any suitable material, according to the requirements of the particular application. Examples of materials suitable for forming metallization layer 28 include, but are not limited to copper and the like.

FIG. 6 illustrates an example electronic assembly 10 at a given stage of processing, in accordance with an embodiment of the present invention. Once the metallization layer 28 is deposited on top of the layer of BLM 22, mask 24 (not shown) may be removed. For example, the mask 24 (not shown) may be stripped from on top of the layer of BLM 22.

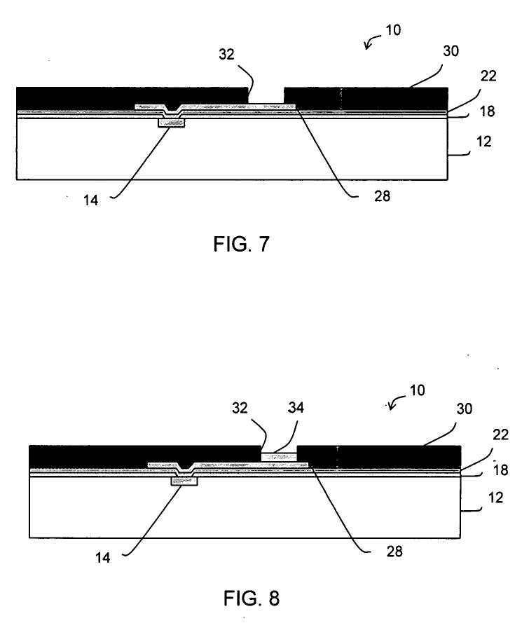

FIG. 7 illustrates an example electronic assembly 10 at a given stage of processing, in accordance with an embodiment of the present invention. Once the mask 24 (not shown) is removed, a second mask 30 may be applied over the metallization layer 28 and/or BLM 22. The second mask 30 may be patterned to expose at least a portion of the metallization layer 28 through a second exposure 32. For example, the second mask 30 may be spun on, cured, exposed, and patterned to form second exposure 32 over the metallization layer 28.

FIG. 8 illustrates an example electronic assembly 10 at a given stage of processing, in accordance with an embodiment of the present invention. Once the second mask 30 is patterned to form second exposure 32, a solder bump 34 may be deposited on top of the metallization layer 28. The solder bump 34 may be deposited by any suitable method, according to the requirements of the particular application. Examples of methods suitable for depositing the solder bump 34 include, but are not limited to electroplating, electroless plating, physical vapor deposition (PVD), and the like. The solder bump 34 may be formed of any suitable material, according to the requirements of the particular application. Examples of materials suitable for forming solder bump 34 include, but are not limited to lead based solder materials, non-lead based solder materials and the like. For the purpose of this application, the term “solder bump” as used herein are to be accorded a broad meaning, including “solder bumps” of any variety of suitable materials (including but not limited to lead, cooper and the like), used in a wide range of packaging techniques (including but not limited to flip-chip), and processes (including but not limited to C4).

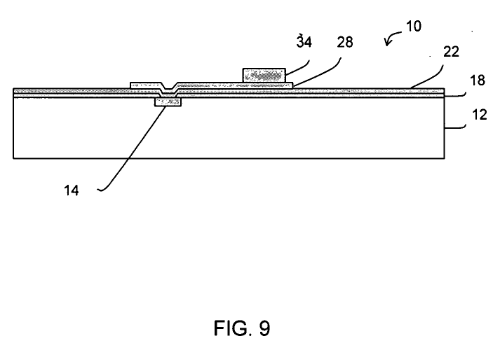

FIG. 9 illustrates an example electronic assembly 10 at a given stage of processing, in accordance with an embodiment of the present invention. Once the solder bump 34 is deposited on top of the layer of metallization layer 28, second mask 30 (not shown) may be removed. For example, the second mask 30 (not shown) may be stripped from on top of the metallization layer 28 and/or BLM 22.

FIG. 1 illustrates an example electronic assembly 10 at a given stage of processing, in accordance with an embodiment of the present invention. Once the second mask 30 (not shown) is removed, a portion of the BLM 22 may be removed. For example, BLM 22 may be removed substantially everywhere except for those portions of BLM 22 that are directly under the metallization layer 28. Examples of methods suitable removing a portion of the BLM 22 include, but are not limited to etching and the like. Further, the portion of the BLM 22 and second mask 30 (not shown) may either be simultaneously removed, or may be separately removed.

The non-removed portion of the BLM 22 and the metallization layer 28 forms a solder terminal 36. The solder terminal 36 may contact both the bond pad 14 and passivation layer 18. The solder terminal 36 is oriented and arranged so that the solder bump 34 contacting the solder terminal 36 may be positioned laterally offset from the bond pad 14. As illustrated, an offset distance A may be established by the solder terminal 36 between a centerline axis B of solder bump 34 and a centerline axis C of bond pad 14. Further, the solder bump 34 may be positioned laterally offset from the bond pad 14 so that the solder bump 34 and bond pad 14 do not overlap.

The solder terminal 36 may be oriented and arranged for any suitable design, orientation, pitch and dimension (including offset distance A) according to the requirements of the particular application. For example, an approximately 84-107 μm diameter solder bump 34 may be offset from the bond pad 14 by an offset distance A of approximately 84-115 μm, or other suitable distance, according to the requirements of the particular application. It will be understood that other thicknesses of solder bump 34 as well as other offset distances A, may be utilized without departing from the scope of the present invention.

The offset distance A between the solder bump 34 and the bond pad 14 changes the stress applied on the semiconductor substrate 12 away from the bond pad 14 due to a later assembly process involving the electronic assembly 10. Further, the materials for the passivation layer 18 may be selected to optimize the compliance of the passivation layer 18, also reducing the stress induced on the semiconductor substrate 12 due to a Later assembly process involving the electronic assembly 10.

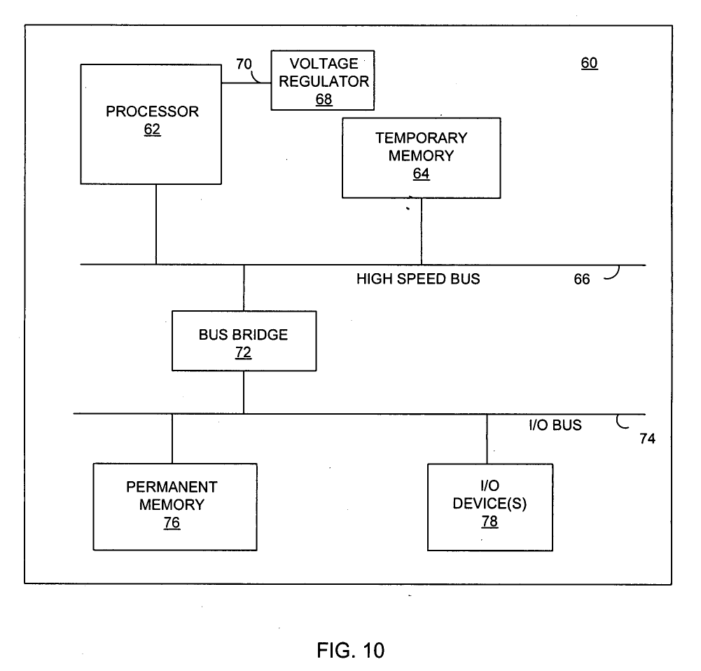

FIG. 10 illustrates a block diagram of one of many possible electronic systems 60 in which embodiments of the present invention may be used. The electronic system 60 may utilize one or more embodiments of the electronic assembly 10 described herein. As shown, the system 60 includes a processor 62, such as an integrated circuit, and temporary memory 64, such as SDRAM and DRAM, on high-speed bus 66. Voltage regulator 68 may be utilized to provide power to processor 62 via traces 70. The high-speed bus 66 is connected through bus bridge 72 to input/output (I/O) bus 74. I/O bus 74 connects permanent memory 76, such as flash devices and mass storage device (e.g. fixed disk device), and I/O devices 78 to each other and bus bridge 72. In various embodiments, system 60 may be a set-top box, a digital camera, a media player, a CD player, a DVD player, a wireless mobile phone, a tablet computing device, or a laptop computing device.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method, comprising:
placing a solder terminal on a bond pad and a passivation layer; and
placing a solder bump on the solder terminal, the solder bump positioned laterally offset from the bond pad.

2. The method of claim 1, further comprising placing the passivation layer on a semiconductor substrate prior to the placing of the solder terminal.

3. The method of claim 2, further comprising forming the passivation layer with a single layer of material.

4. The method of claim 1, wherein the passivation layer is selected from the group consisting of silicon nitride, silicon oxide, silicon oxynitride, polyimide/silicon nitride, polyimide/silicon oxide, polyimide/silicon oxynitride and combinations thereof.

5. The method of claim 1, wherein the placing of the solder terminal comprises depositing a layer of barrier layer metallurgy on the bond pad and the passivation layer, and plating a metallization layer plated on top of the barrier layer metallurgy.

6. The method of claim 5, wherein the placing of the solder bump comprises plating copper onto the metallization layer of the solder terminal.

7. The method of claim 1, wherein the solder bump is positioned laterally offset from the bond pad so that the solder bump and bond pad do not overlap.

8. An apparatus comprising:
a semiconductor substrate having a bond pad and a passivation layer located on an active surface thereof;
a solder terminal contacting both the bond pad and passivation layer; and
a solder bump contacting the solder terminal and positioned laterally offset from the bond pad.

9. The apparatus of claim 8, wherein the passivation layer is formed of a single layer of material.

10. The apparatus of claim 8, wherein the passivation layer is selected from the group consisting of silicon nitride, silicon oxide, silicon oxynitride, polyimide/silicon nitride, polyimide/silicon oxide, polyimide/silicon oxynitride and combinations thereof.

11. The apparatus of claim 8, wherein the solder terminal includes a metallization layer plated on top of a layer of barrier layer metallurgy.

12. The apparatus of claim 11, wherein the solder bump includes copper formed on the metallization layer of the solder terminal.

13. The apparatus of claim 8, wherein the solder bump is positioned laterally offset from the bond pad so that the solder bump and bond pad do not overlap.

14. A system comprising:
an integrated circuit comprising:
a semiconductor substrate having a bond pad and a passivation layer located on an active surface thereof,
a solder terminal contacting both the bond pad and passivation layer, and
a solder bump contacting the solder terminal and positioned laterally offset from the bond pad;
a bus coupled to the integrated circuit; and
a mass storage coupled to the bus.

15. The system of claim 14, wherein the system is selected from the group consisting of a set-top box, a digital camera, a media player, a CD player, a DVD player, and a wireless mobile phone.

16. The system of claim 14, wherein the passivation layer is formed of a single layer of material.

17. The system of claim 14, wherein the passivation layer is selected from the group consisting of silicon nitride, silicon oxide, silicon oxynitride, polyimide/silicon nitride, polyimide/silicon oxide, polyimide/silicon oxynitride and combinations thereof.

18. The system of claim 14, wherein the solder terminal includes a metallization layer plated on top of a layer of barrier layer metallurgy.

19. The system of claim 18, wherein the solder bump includes copper formed on the metallization layer of the solder terminal.

20. The system of claim 14, wherein the solder bump is positioned laterally offset from the bond pad so that the solder bump and bond pad do not overlap.
